(19) United States
(12) Patent Application Publication
(10) Pub. No.: US 2010/0089437 A1
(43) Pub. Date: Apr. 15, 2010

(54) VEHICLE-BASED SOLAR CONCENTRATOR

(76) Inventors: JOHN F. FEDERSPIEL, Rochester, MI (US); Chris Churchill, Ypsilanti, MI (US); Charles S. Hutchins, North Palm Beach, FL (US); Sarah Napier, Clarkston, MI (US); Matthew Ross, Chicago, IL (US); Cameron Wylie, Woodside, NY (US)

Correspondence Address: HARNESS, DICKEY & PIERCE, P.L.C., P.O. BOX 828, BLOOMFIELD HILLS, MI, 48303, US

(21) Appl. No.: 12/579,487

(22) Filed: Oct. 15, 2009

Related U.S. Application Data
(60) Provisional application No. 61/105,437, filed on Oct. 15, 2008.

(51) Int. Cl. H01L 31/052

(52) U.S. Cl. 136/246

(57) ABSTRACT

A vehicle-based solar collector comprising a cylindrical array of concentrator cells, a heat sink coupled to the linear array of concentrator cells, and a plurality of modules running fore and aft in the car, wherein each of the plurality of modules has a parabolic trough mirror that reflects light onto the cylindrical array of concentrator cells.

### CROSS-REFERENCE TO RELATED APPLICATIONS

This application claims the benefit of U.S. Provisional Application No. 61/105,437. filed on Oct. 15, 2008. The entire disclosure of the above application is incorporated herein by reference.

### FIELD

The present disclosure relates to solar concentrators and, more particularly, relates to a vehicle-based solar concentrator.

### BACKGROUND AND SUMMARY

This section provides background information related to the present disclosure which is not necessarily prior art. This section also provides a general summary of the disclosure, and is not a comprehensive disclosure of its full scope or all of its features.

The global energy crisis of 1973 created an incentive to move away from petrochemical sources (including coal, oil and natural gas) of energy production into more renewable sources such as solar and wind power. One of the strongest effects of the embargo on oil sales to the US, Japan and Western Europe was a sharp increase in gasoline prices and a new (and perhaps for the first time) focus on fuel economy for automotive vehicles. The end of the embargo and the drop in gas prices reduced, at least temporarily, the economic pressure on finding replacement or supplemental power sources for such vehicles, and the relatively few non-petrochemical-based vehicle power supplies have generally been either biologically based fuels (such as ethanol) or driven by chemical (typically lead-acid) batteries. More recently the increased global demand for oil and the prospect of exhausting the world's extractable oil supplies have renewed the consideration of alternate power supplies for automobiles and homes.

To inspire innovation and bring attention to the use of alternate power sources for automobiles including solar power, many annual or periodic races have been held where solar-powered cars compete, including the North American Solar Challenge and the World Solar Challenge in Australian outback. The designs of most of these vehicles include the covering of most every square centimeter of their top surfaces in photovoltaic (PV) solar cells. Typically these cells have employed silicon-based (“Group IV” elemental semiconductors) designs but more recently so-called “Group III-V” semiconductors, or combinations of Group IV and Group III-V materials, have been used. For these competitions, car designs are intended to maximize the possible speed attainable solely through the use of solar power. The total cell collecting area of these cars is approximately 6 square meters and these systems generate between 1.5 and 2 kilowatts of peak power in operation. These power levels are also appropriate for noncompetitive vehicle use, such as the recent examples of electric or hybrid-electric vehicles (HEVs), although the designs of “daily use” cars would differ radically, mostly for reasons of comfort, cargo and passenger capacity and durability.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a photograph illustrating an upper surface of a vehicle-based solar concentrator according to the principles of the present teachings;

FIG. 2A is a photograph illustrating the components of the solar concentrator, with portions removed for clarity, according to the principles of the present teachings;

FIG. 2B is an enlarged photograph illustrating the components of the solar concentrator, with portions removed for clarity;

FIG. 3 is a schematic view of a mirror support according to the principles of the present teachings;

FIG. 4 is a graph illustrating the cell spectral absorbance of the solar concentrator;

FIG. 5 is a graph illustrating the dependency of cell efficiency on solar concentration and temperature;

FIG. 6 is a photograph illustrating an interior view of the vehicle-based solar concentrator according to the principles of the present teachings;

FIG. 7 is a graph illustrating the reflectance of Alanod MiroSilver across the spectrum;

FIG. 8 is a graph illustrating the transmission of acrylic across the spectrum;

FIG. 9 is a perspective view illustrating the components of the solar concentrator, with portions removed for clarity, according to some embodiments of the present teachings;

FIG. 10 is an end view illustrating the components of the solar concentrator, with portions removed for clarity, according to some embodiments of the present teachings; and

FIG. 11 is a graph illustrating solar energy collection relative to time of day.

Corresponding reference numerals indicate corresponding parts throughout the several views of the drawings.

### DETAILED DESCRIPTION

Example embodiments will now be described more fully with reference to the accompanying drawings. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

### Technical Rationale

Other solar power collection and/or generation methods must be contemplated in order to maintain vehicle aesthetics and functionality similar to those in current use. In some embodiments, a design criterion is that the solar cells should be concealed as much as possible from the outside, every-day spectator. Further, in some embodiments, the location of these devices should be placed in a nonessential area and should not extensively occupy too much space. One way to accomplish this is to use high efficiency concentrating photovoltaics (CPV) which use lenses or mirrors to focus light to many times the sun's intensity. For example, triple junction solar cell technology, from GaInP/GaInAs/Ge produced at Spectrolab, have achieved the highest efficiency ever reported of 40.7% at 240 suns measured under the ASTM G173-03 spectrum from a champion cell. Presently, production efficiencies are 37.5% for a 1×1 cm² multijunction device. When operated under concentrated sunlight, a multijunction CPV system with much less cell area than a Si panel can generate almost twice as much power.

### Technical Approach

In order to lessen our dependence on power produced from the combustion engine in automobiles but yet maintain its customary body style image, a designated volume of space must be allocated in the vehicle for PV power generation. One such location can be in the back of the vehicle with some tradeoff of trunk space. A lightweight CPV system could be designed to operate at low concentration levels, or solar flux. An array that consists of optimally-designed multijunction cells of 35% efficiency would use a small aperture area to allow sunlight to enter in the vehicle's cavity to provide power at 500 W. Factors such as cell efficiency, mirror reflectivity, heat dissipation, concentration level, etc., all of which affect the multijunction solar cell performance, would be part of a trade space study to reduce the aperture area and therefore increase cargo area. Since heat dissipation is imperative to minimize their performance degradation, the most efficient system (and economical) can be one that will use either an actively- or passively-cooled configuration together with properly-devised heat rejection schemes. The small array can employ a unique 2-axis tracker that will not require high accuracy to track the sun, with components possibly purchased from off-the-shelf. The acceptance angle of light that impinges on the solar cells will depend on the angular aperture area which is given by:

θ=2 tan⁻¹ [NW/(2(f+Hᵣₐ)]

where N is the number of PV modules, W is the width of a single module, f the focal length of each curved mirror and Hᵣₐ is the height of the receiver assembly.

Design, fabrication and characterization of high efficiency solar cells took place at Spectrolab. The High Intensity Pulsed Solar Simulator was used to test the cells and generate IV characteristics which will assess cell performance. Spectrolab's thermal management expertise has solved heat transfer problems with FEA (ANSYS) and finite difference techniques.

The PV array of the present teachings has several benefits that will make it attractive for use in electric vehicles and in HEVs:
1) Battery charging can take place while the vehicle is moving in any direction.
2) Battery charging can occur while the vehicle is stationary. A similar technique uses a trickle charger composed of a small flat-plate amorphous cell collector which provides a miniscule amount of power, taking several months at 8 hours/day to fully charge one car battery at 40 Whr. With the PV array, however, it would take a little more than 4 hours to provide half of the full charge.
3) Minimal surface area usage of the vehicle for solar cells.

### Overview of Prior Work

The concept of incorporating a prototype CPV array in a solar vehicle to supplement power to larger-area, one-sun solar cells, has already been shown. A peak power of 300 W was designed for the array which delivered 270 W to the electric motor under normal conditions. The present teachings, however, use the ideas already folded into this technology but with performance improvements to generate higher power solar cells to meet 500 W, and mechanical stability and optical enhancements to produce high performance modules.

### Additional Description

The Solar Concentrator was devised as a result of a shift in regulations in the 2007 Panasonic World Solar Challenge. For prior races, vehicles were required to fit within a prescribed 5 m×1.8 m×1.6 m box. Within this box, teams were permitted to place on their car as many solar cells as they could fit. In 2007, this changed with the inception of the challenge class. One of the stipulations of entering the challenge class was that while cars still were limited by the same size restrictions, a new limit was placed on solar cell area. Cars were permitted to have no more than six square meters of solar cells. In order to maximize solar energy collected, the University of Michigan Solar Car Team developed a vehicular solar concentrator system.

This system was designed exclusively for the World Solar Challenge, resulting in some significant design considerations. The peak power absorbed by the array was close to 2000 watts. The solar car traveled at speeds near 110 kilometers per hour on the race. To achieve this speed, it was important that power gains were maximized and power losses through aerodynamics and rolling resistance (a consequence of additional weight) were minimized. In general, the concentrator system needed to be one that fit perfectly within the car's designed body, weigh as little as possible, and generate as much power as possible.

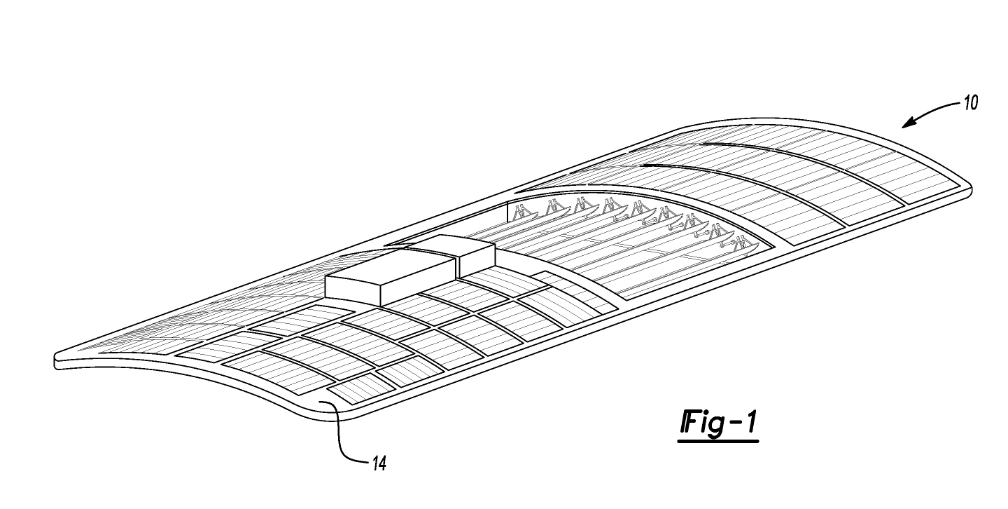

A concentrator system also introduced many new considerations. To maximize power gained, all optical surfaces needed to be as clean as possible, meaning that the concentrator region needed to be isolated from the elements. Also, an increase in solar concentration dramatically increased the heat generated in this region of the vehicle. This heat needed be removed not only to improve solar cell performance, but also for driver for safety purposes. FIG. 1 shows the upper surface of the solar car with the standard cells and the concentrator system.

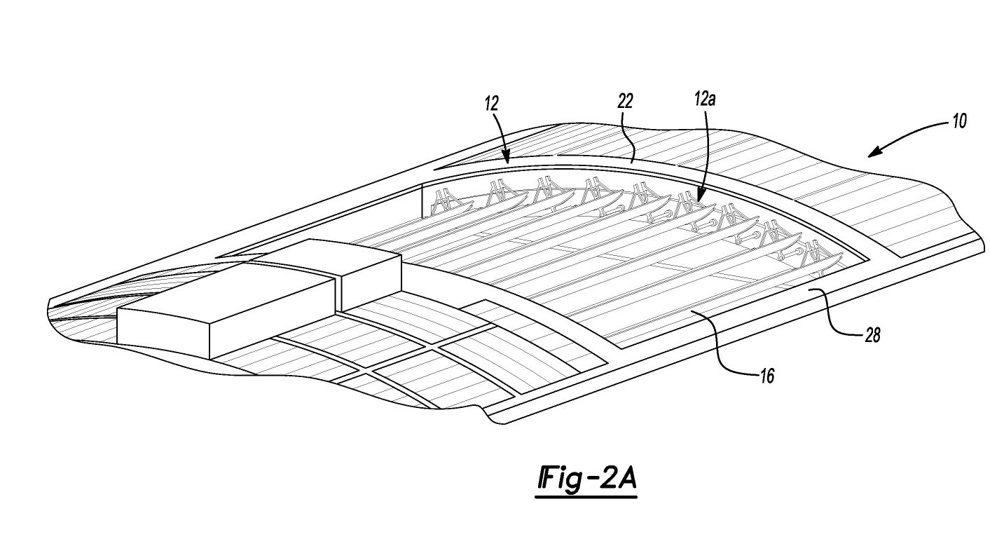

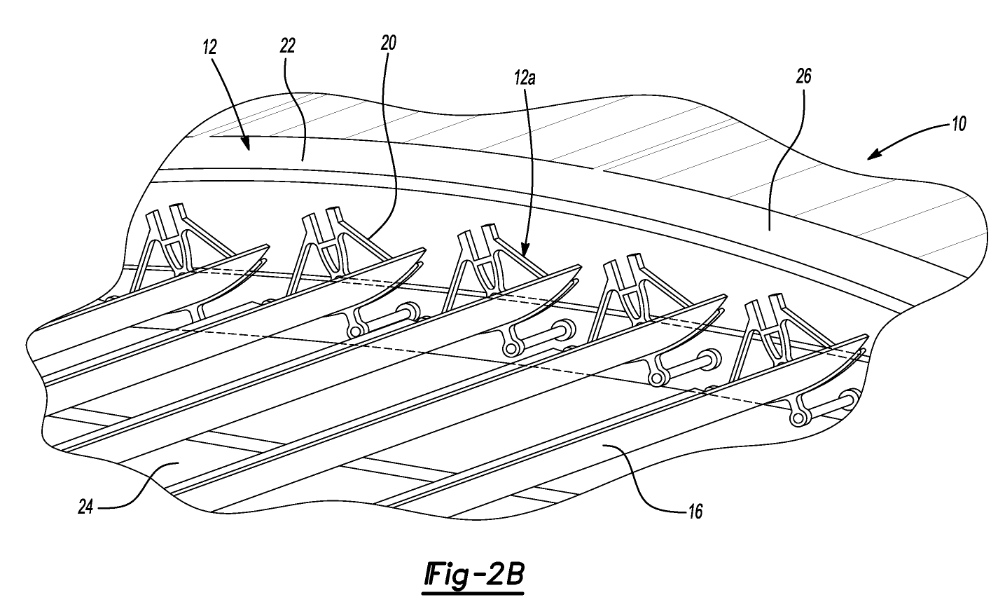

The general configuration of the concentrator system 10 comprises about 10 parallel modules 12 running fore and aft in the car 14. Each module 12 includes a parabolic trough mirror 16 that reflects light onto a linear array of concentrator cells 18 that are attached to an aluminum heat sink 20. The system 10 occupies a 1150 mm×1610 mm box 22, with the height varying with the curvature of the car 14. Of the ten modules 12, four larger modules 12A lie in the center of the vehicle 14. FIG. 2 shows the mechanical system of the concentrators 18.

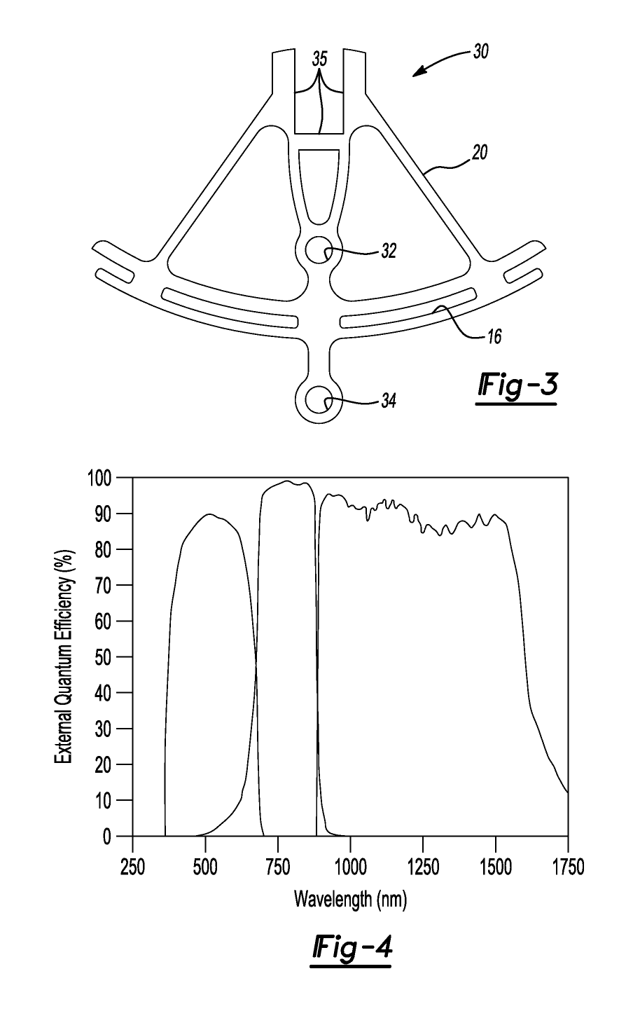

In some embodiments, the walls and floor of the concentrator box 22 are made of carbon fiber panels 24. The bulkhead support bars 26 can be bolted to the fore and aft vertical panels 28. Then the mirror supports 30 are attached with shoulder screws to the bulkhead supports 26. Nylon bushings can be used in the mirror supports 30 to allow free rotation. The mirrors 16 and heat sinks 20 are held rigidly together at each end by the mirror supports 30, shown in FIG. 3.

The heat sinks 20 screw into the top of the support 30 and set screws are used to hold the mirrors 16 in the part of the support 30 that is the exact curvature of the mirror 16. The mirror supports 30 are connected at their center of rotation 32 to the bulkhead supports 26. The actuating bar 34 is connected to the bottom of all the mirror supports 30, and a simple linkage (not shown) allows a linear actuator to move this bar 34 linearly back and forth, causing the mirror supports 30 to rotate about the center point 32 between the mirror 16 and the cells 18.

In some embodiments, on the flat sides 35 of each heat sink extrusion 20, there are two parallel strings of 36 solar cells 18 in series. These solar cells 18 come in a preexisting package with a positive contact on the upper 40% of the cell's backside and the negative contact on the lower 40%. These cells are designed to absorb the light spectrum as shown in FIG. 4.

The cell efficiency also increases as concentration is increased. This increase in efficiency is the main reason why we constructed two different sizes of mirrors. The larger mirrors concentrate at an average of 24 suns while the smaller mirrors are at an average of 13 suns. There is, however, one significant drawback to using larger mirrors—losses due to an increase in temperature. As temperature increases, there is a significant decrease in cell efficiency. FIG. 5 shows the dependency of cell efficiency on temperature and concentration.

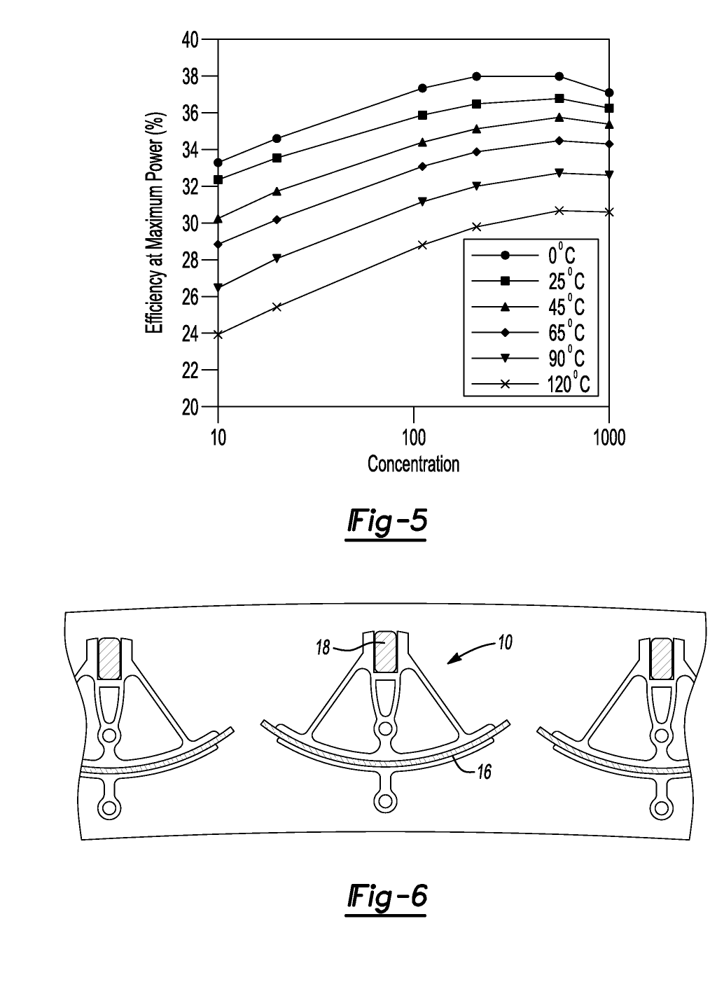

Mirrors 16 were chosen as the concentrating optical element for minimal optical losses, manufacturing simplicity, and weight. The reflective mirrors were made by bending 0.02 inch thick Alanod MiroSilver into a specified parabolic shape. Each Parabola weighs approximately 1 pound. The shape of the parabola is an intersection of two parabolas at the vertex. Each half of the parabola spreads the light across 20% of the cells center. The reason for intersection two parabolas is that if one half is shaded by another module, then the light distribution across cell surface remains constant—intensity only varies. In some embodiments, mirrors 16 can focus on 20% of the cell to allow for flexibility in tracking. The sun can be off the normal of mirror by ±1.1 degrees. In some applications, this may be optimal because the maximum suspension travel is approximately ±0.5 degrees allowing an additional 1.2 degrees of tracking error. The entire system can be designed to rotate ±68 degrees from the normal to the road's surface. This enables full tracking from 8 am to 5 pm in Australia during the race. FIG. 6 shows an interior view of the system with concentrated beam on the center of the cell's surface.

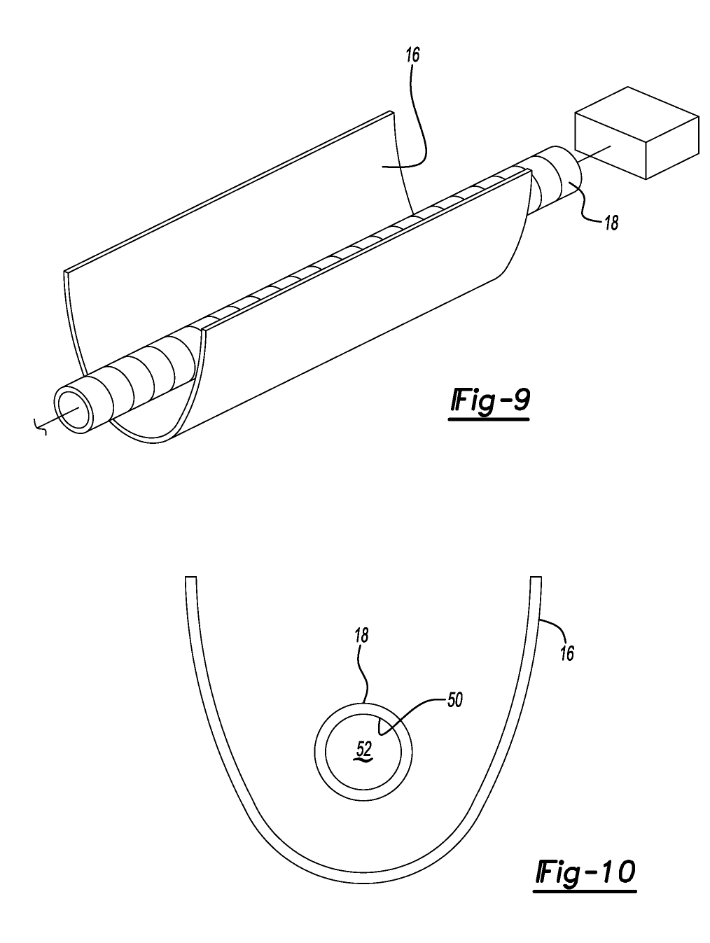

In some embodiments, as illustrated in FIGS. 9 and 10, solar cells 18 can be cylindrical. That is, solar cells 18 can comprise a central cylindrical base housing 50, such as a copper pipe, having a plurality of solar cells 18 disposed about the outer periphery of the cylindrical base housing 50. These solar cells 18 can extend the length of the central cylindrical base housing 50 to form a cell assembly that can be illuminated from any position thereabout. It should be appreciated that in some embodiments, central cylindrical base housing 15 can be eliminated or integrally formed with solar cells 18 to form a cylindrical solar cell arrangement.

In some embodiments, cylindrical solar cells 18 can comprise a hollow central core 52 for receiving a fluid therein. The fluid can be a flowing fluid used to cool solar cells 18 and improve the overall efficiency of the system. A fluid pump can be used to actively circulate the fluid through hollow central core 52. As described herein, solar cells typically lose efficiency with an increase in operating temperature (see FIG. 5). Therefore, by providing a central fluid core, the fluid can receive and transfer heat from solar cells 18 and carry such thermal energy away from solar cells 18. The heated fluid can be used for additional power generation, if desired.

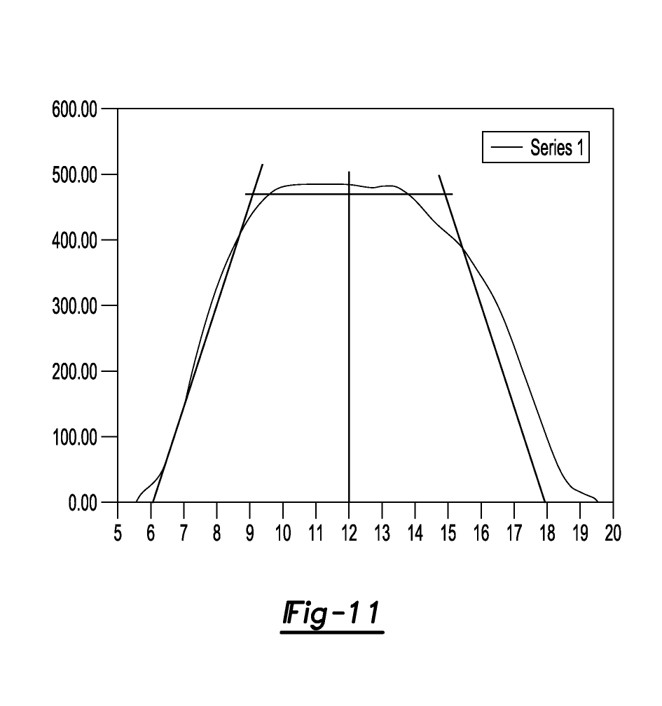

Solar cells 18, whether having a linear or cylindrical shape, can be paired with parabolic-shaped mirrors 16 to concentrate sun light upon cylindrical solar cells 18. It has been determined that solar cells 18 generally maintain their highest efficiency even when illuminated with light at angles of incidence less than 90 degrees to a point where efficiency quickly decreases. As seen in FIG. 11, when viewed in terms of solar radiation output relative to time of day (and assume a peak illumination at 12 o'clock noon), it can be seen that solar radiation is maximized from about 9 o'clock in the morning to 3 o'clock in the afternoon. The angles of incidence that are represented by this period can be used to determine the shape of the parabolic mirrors 16 to maximize the portion of solar cells 18 exposed to such illumination. In some embodiments, mirrors 16 can be made of polished stainless steel having a Nomex core and a graphite back surface to achieve the necessary stiffness and light weight.

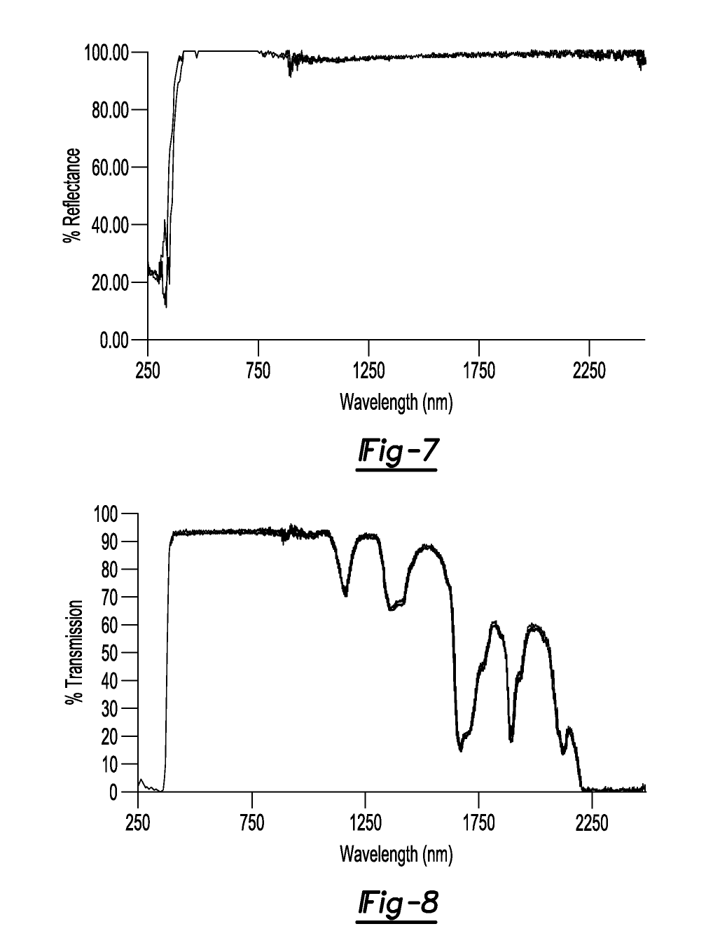

The reflectivity of the Alanod MiroSilver across the spectrum is shown below in FIG. 7, based on the testing of two samples in a spectrophotometer.

In some embodiments, it may be important that the concentrators be in a sealed box to minimize the aerodynamic losses, and to keep out dirt and dust. Therefore, an optically clear cover may be needed that would match the curvature of the upper surface of the car, while also minimizing optical losses. A molded acrylic window was chosen to maximize light transmission and to minimize weight. Refraction for the majority of the window was considered negligible. The light transmission for the acrylic is shown in FIG. 8, based on the testing of two samples in a spectrophotometer.

On the flat side of each extrusion there are 2 parallel strings of 36 cells in series. Between each parallel string a blocking diode is inserted to prevent any “current drops.” The cells face the mirrors and are adhered to the extrusion via Arctic Silver low viscosity ceramic adhesive. This adhesive is both thermally conductive and electrically insulating. Each cell is 10×15 mm with a positive and negative pad on the backside. The cells are wired in series by a tab of 1 mm silver with the short sides touching. For convenience the cells are rotated 180 degrees so that a positive contact is adjacent to a negative contact. The parallel strings of each extrusion are run in parallel with each other to a single Biel maximum power point tracker (MPPT). This MPPT determines the maximum power that can be obtained from the entire system and delivers it to the battery.

Terrestrial based concentrator systems usually have larger heat sinks to dissipate the excess solar energy. Cars do not have the capability for large heat sinks because of space and weight.

In some embodiments, it may be important to have an active cooling system for the concentrators for two reasons: first, because the high temperatures can affect the surrounding materials in a negative way and second, because the efficiency of the solar cells decreases with increasing temperatures. The cooling system can be designed to be lightweight and consume the smallest amount of power possible. The strings of cells were mounted using an electrically insulating, but thermally conductive adhesive to aluminum heat sink extrusions. The concentrator box can be completely sealed but for 4 large holes in the front end where filters were placed, and 10 circular holes in the rear end where fans were placed. It was important to have filters so that the mirrors and cells were not coated in dust, decreasing the amount of solar radiation received by the cells. Each heat sink extrusion had a temperature sensor, which when the temperature of the heat sink exceeded 80 C, would trigger the fan to turn on. To keep the hot air flowing away from the box and out of the car, two outlet ducts were made under the tail of the car for the air to flow out. A layer of Mylar was also put on the bottom and sides of the concentrator box to help keep the heat out of the box.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A vehicle-based solar collector comprising:
a cylindrical array of concentrator cells;
a heat sink coupled to said linear array of concentrator cells; and
a plurality of modules running fore and aft in the car, each of said plurality of modules having a parabolic trough mirror that reflects light onto said cylindrical array of concentrator cells.

2. The vehicle-based solar collector according to claim 1, further comprising:
a central core extending through said cylindrical array of said concentrator cells; and
a fluid flowing through said central core, said fluid receiving thermal energy from said cylindrical array of said concentrator cells.

3. The vehicle-based solar collector according to claim 1 wherein said cylindrical array of concentrator cells comprises:
a central cylindrical base housing; and
a plurality of solar cells circumferentially surrounding said central cylindrical base housing.

4. The vehicle-based solar collector according to claim 3 wherein said central cylindrical base housing is comprises of copper tubing.

5. The vehicle-based solar collector according to claim 3 wherein said central cylindrical base housing is integrally formed with said plurality of solar cells.

6. A vehicle-based solar collector comprising:
a cylindrical array of concentrator cells having a hollow central volume;
a heat sink coupled to said linear array of concentrator cells;
a plurality of modules running fore and aft in the car, each of said plurality of modules having a parabolic trough mirror that reflects light onto said cylindrical array of concentrator cells;
a fluid pump pumping fluid through said hollow central volume of said cylindrical array of concentrator cells.

7. The vehicle-based solar collector according to claim 6 wherein said cylindrical array of concentrator cells comprises:
a central cylindrical base housing; and
a plurality of solar cells circumferentially surrounding said central cylindrical base housing.

8. The vehicle-based solar collector according to claim 6 wherein said central cylindrical base housing is comprises of copper tubing.

9. The vehicle-based solar collector according to claim 6 wherein said central cylindrical base housing is integrally formed with said plurality of solar cells.
